(19) United States
(12) Patent Application Publication
(10) Pub. No.: US 2009/0117725 A1
(43) Pub. Date: May 7, 2009

(54) METHOD OF MANUFACTURING FLASH MEMORY DEVICE

(76) Inventor: Jong-Won Sun, Gokseong-gun (KR)

Correspondence Address: SHERR & VAUGHN, PLLC, 620 HERNDON PARKWAY, SUITE 200, HERNDON, VA, 20170, US

(21) Appl. No.: 12/263,481

(22) Filed: Nov. 2, 2008

(30) Foreign Application Priority Data
Nov. 5, 2007 (KR) 10-2007-0112135

(51) Int. Cl. H01L 21/28

(52) U.S. Cl. 438/591; 257/E21.21

(57) ABSTRACT

A method of manufacturing a flash memory device includes forming a line pattern over a semiconductor substrate, and then forming a first dielectric spacer having a vertically extending portion formed on sidewalls of the line pattern and a horizontally extending portion formed over and contacting the semiconductor substrate, and then removing the horizontally extending portion of the first dielectric spacer, and then forming a second dielectric spacer layer on the sidewall of the vertically extending portion of the first dielectric spacer and on the area of the semiconductor substrate where the horizontally extending portion of the first dielectric spacer was removed.

The present application claims priority under 35 U.S.C. §119 to Korean Patent Application No. 10-2007-0112135 (filed on Nov. 5, 2007), which is hereby incorporated by reference in its entirety.

### BACKGROUND

A flash memory device is a type of programmable read-only memory (PROM) capable of writing, erasing and reading data. In accordance with a cell array system, flash memory devices can be classified into a NOR-type structure in which cell transistors are arranged in parallel between a bit line and a ground electrode, and a NAND-type structure in which cell transistors are arranged in series. The NOR-type flash memory device, since it is capable of high-speed random access during a reading operation, is generally used for booting a mobile phone. On the other hand, the NAND-type flash memory is appropriate for storing data due to its high-speed writing performance although being slow in reading. The NAND-type flash memory device is advantageous in its capability of achieving high integration.

Flash memory devices can also be classified into a stack gate-type and a split gate-type in accordance with the unit cell structure. Flash memory devices can also be classified into a floating gate device and a silicon-oxide-nitride-oxide-silicon (SONOS) device in accordance with the structure of a charge storage layer. The floating gate device can include a floating gate which includes polycrystalline silicon usually surrounded by insulators. Storing and erasing of data in the floating gate device is performed by injecting and discharging electric charges with respect to the floating gate through the process of channel hot carrier injection or Fowler-Nordheim (F-N) tunneling.

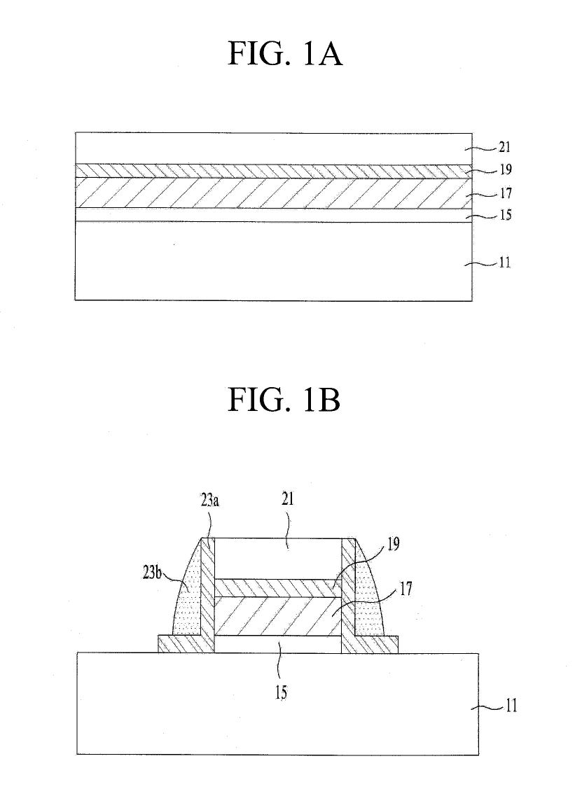

As illustrated in example FIG. 1A, a method of manufacturing a flash memory device can include forming a plurality of device isolation layers spaced by predetermined intervals on and/or over semiconductor substrate 11. The device isolation layers are arranged parallel with one another in a bit line direction, thereby defining active device regions. Wells are formed in the active device regions of semiconductor substrate 11. For example, in case of a P-type substrate, after N-wells, which are relatively deep, are formed, pocket P-wells are then formed. Next, a cell threshold voltage is determined through implantation, and then tunnel oxide layer 15 and floating gate layer 17 are formed in the active device region. Floating gate 17 is made of polysilicon applied with dopants. Oxide-nitride-oxide (ONO) layer 19 and control gate layer 21 are formed in sequence on and/or over the whole surface of semiconductor substrate 11. Control gate 21 is made of a silicon oxide layer.

As illustrated in example FIG. 1B, tunnel oxide layer 15, floating gate 17, ONO layer 19 and control gate 21 are then patterned by partially removing portions by a predetermined width in a direction vertical to the device isolation layer. As a result of such patterning, a plurality of stacks are formed, the stacks each including tunnel oxide layer 15, floating gate 17, ONO layer 19 and control gate 21. The stacks will be referred to as line patterns hereinafter. After formation of the line patterns, a dielectric layer is formed on and/or over the whole surface of semiconductor substrate 11. Dielectric spacer layers 23 are produced through an etch-back process, on sidewalls of the respective line patterns. Dielectric spacer layers 23 include oxide layer 23a and nitride layer 23b. Afterward, source/drain regions are formed by ion implantation and additionally, a contact hole forming process, a drain contact forming process and a metal line forming process are performed.

In accordance with the above-described method for manufacturing a flash memory device, however, the ions implanted in the floating gate may escape through an interface between the oxide layer and the nitride layer as the device size is reduced, thereby inducing damage of the data.

### SUMMARY

Embodiments relate to a manufacturing method for a flash memory device that prevents loss and/or damage to data.

Embodiments relate to a method for manufacturing a flash memory device that may include at least one of the following steps: forming a plurality of device isolation layers parallel with one another at predetermined intervals on and/or over a semiconductor substrate, and then forming a gate stack by sequentially depositing a tunnel oxide layer, a floating gate, an ONO layer, and a control gate on and/or over the semiconductor substrate including the device isolation layer, and then forming a first dielectric spacer layer on side walls of each gate stack including the tunneling oxide layer, the floating gate, the ONO layer, and the control gate, and then etching part of the first dielectric spacer layer, and forming a second dielectric spacer layer on lateral sides of the first dielectric spacer layer.

Embodiments relate to a method for manufacturing a flash memory device that may include at least one of the following steps: forming a plurality of device isolation layers in parallel at predetermined intervals over a semiconductor substrate; and then forming a gate stack including a tunnel oxide layer, a floating gate, an ONO layer, and a control gate over the semiconductor substrate including the device isolation layers; and then forming a first dielectric spacer on sidewalls of the gate stack; and then etching a portion of the first dielectric spacer layer; and then forming a second dielectric spacer layer over a sidewall of the first dielectric spacer layer after etching the portion of the first dielectric spacer layer.

Embodiments relate to a method that may include at least one of the following steps: forming a plurality of device isolation layers over a semiconductor substrate defining active regions; and then sequentially forming a first oxide layer, a doped polysilicon layer, a second oxide layer, a first nitride layer, a third oxide layer, and a fourth oxide layer over a semiconductor substrate; and then forming a line pattern including a tunnel oxide pattern, a floating gate pattern, an ONO pattern and a control gate pattern by patterning the first oxide layer, the doped polysilicon layer, the second oxide layer, the first nitride layer, the third oxide layer and the fourth oxide layer; and then forming a fifth oxide layer over the whole surface of semiconductor substrate including the line pattern; and then forming a first spacer by etching the fifth oxide layer, the first spacer having a first spacer portion extending vertically on and contacting sidewalls of the line pattern and a second spacer portion extending horizontally over and contacting the uppermost surface of the semiconductor substrate; and then removing the second spacer portion; and then forming a second nitride layer over the whole surface of the semiconductor substrate including the first spacer; and then forming a second spacer on the first spacer portion and over an area of the semiconductor substrate where the second spacer portion was removed.

Embodiments relate to a method that may include at least one of the following steps: forming a plurality of device isolation layers over a semiconductor substrate defining active regions; and then sequentially forming a tunnel oxide layer, a floating gate layer, an ONO layer and a control gate layer over the whole surface of the semiconductor substrate; and then forming a line pattern including a tunnel oxide pattern, a floating gate pattern, an ONO pattern and a control gate pattern by patterning the tunnel oxide layer, the floating gate layer, the ONO layer and the control gate layer; and then forming a first dielectric layer over the whole surface of the semiconductor substrate including the line pattern; and then forming a first dielectric spacer by performing an etch-back process on the first dielectric layer, the first dielectric spacer having a vertically extending portion formed on sidewalls of the line pattern and a horizontally extending portion formed over and contacting the semiconductor substrate; and then performing an etch process to remove the horizontally extending portion of the first dielectric spacer; and then forming a second dielectric layer over the whole surface of the semiconductor substrate including the first dielectric spacer; and then forming a second dielectric spacer layer on the sidewall of the vertically extending portion of the first dielectric spacer and on the area of the semiconductor substrate where the horizontally extending portion of the first dielectric spacer was removed.

### DRAWINGS

Example FIGS. 1A to FIG. 1B illustrate a method of manufacturing a flash memory device.

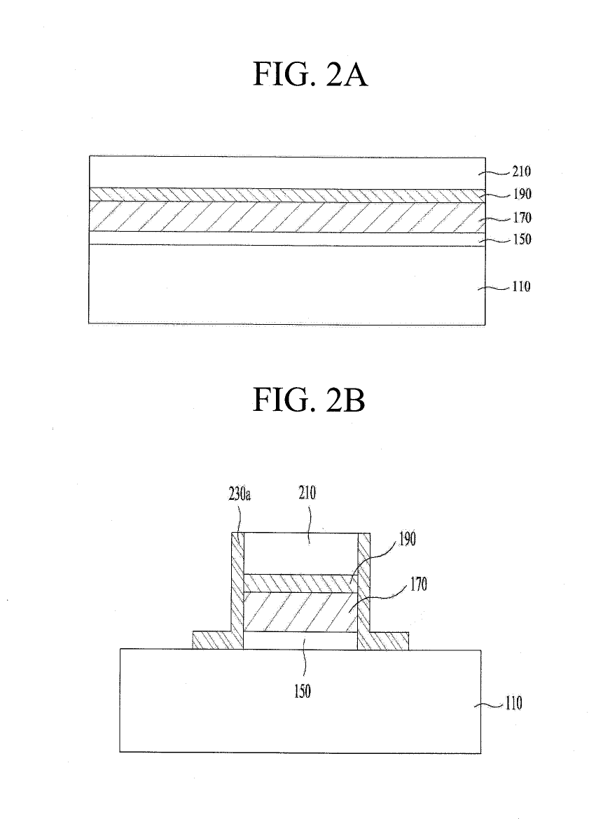

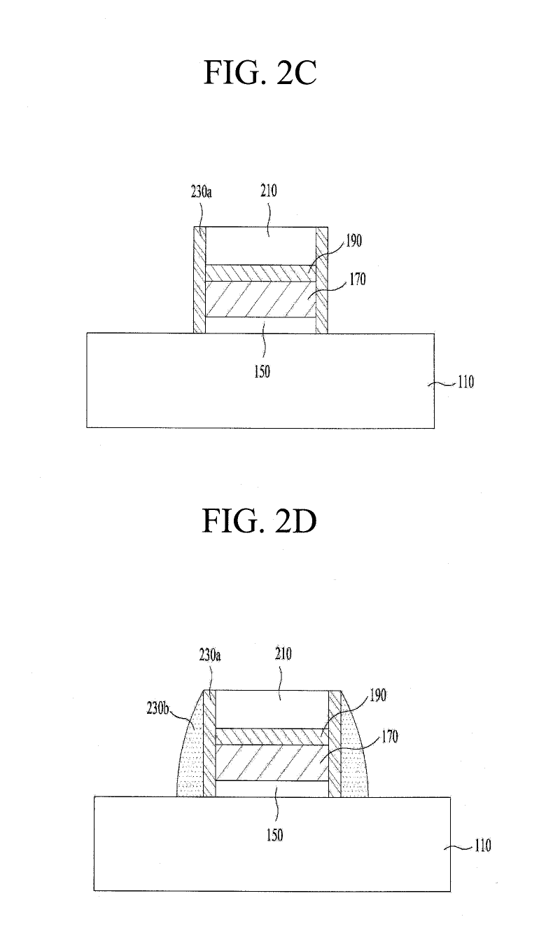

Example FIGS. 2A to FIG. 2D illustrate a method of manufacturing a flash memory device in accordance with embodiments.

### DESCRIPTION

Reference will now be made in detail to embodiments, examples of which are illustrated in the accompanying example drawing figures. Wherever possible, the same reference numbers will be used throughout the example drawing figures to refer to the same or like parts.

As illustrated in example FIG. 1, a plurality of device isolation layers are initially formed spaced by predetermined intervals on and/or over semiconductor substrate 110. The device isolation layers are arranged parallel with one another in a bit line direction, thereby defining active device regions. Wells are formed in the active device regions of semiconductor substrate 110. For example, in case of a P-type substrate, after N-wells, which are relatively deep, are formed, pocket P-wells are then formed. Next, a cell threshold voltage is determined through implantation, and then tunnel oxide layer 150 and floating gate layer 170 are formed in the active device region. Floating gate layer 170 is made of polysilicon applied with dopants. ONO layer 190 and control gate layer 210 are formed in sequence on and/or over the whole surface of semiconductor substrate 110. Control gate layer 210 is made of a silicon oxide layer.

As illustrated in example FIG. 2B, tunnel oxide layer 150, floating gate layer 170, ONO layer 190 and control gate layer 210 are patterned by partially removing portions thereof by a predetermined width in a direction vertical to the device isolation layer. As a result of such patterning, a plurality of stacks (e.g., line patterns) are formed, the stacks each including tunnel oxide layer 150, floating gate 170, ONO layer 190 and control gate 210. After formation of the line patterns, a first dielectric layer composed of an oxide material is formed on and/or over the whole surface of semiconductor substrate 110. First dielectric spacer layer 230a is formed through an etch-back process having a vertically extending portion formed on sidewalls of the line pattern and a horizontally extending portion formed on and/or over semiconductor substrate 110.

As illustrated in example FIG. 2C, the horizontally extending portion of first dielectric spacer layer 230a, the portion corresponding to a position of a second dielectric spacer layer 230b, is removed.

As illustrated in example FIG. 2D, a second dielectric layer composed of a nitride material is formed on and/or over the whole surface of semiconductor substrate 110 including first dielectric spacer layer 230a, and then second dielectric spacer layer 230b is formed through dry etching of the nitride dielectric layer. Accordingly, an interface between first dielectric spacer layer 230a and second dielectric spacer layer 230b is protected by second dielectric spacer layer 230b, such that escape of ions implanted in floating gate 170 through the interface can be prevented. Next, a source/drain region forming process through ion implantation, a contact hole forming process, a drain contact forming process and a metal line forming process are additionally performed.

As apparent from the above description, in accordance with embodiments, a method of manufacturing a flash memory device can be accomplished in which a tunnel oxide layer subject to loss of data is protected by dielectric spacer layers. Thereby, the prevention of separation of electrons and holes can be achieved and loss and/or damage of data stored in the flow memory device can be prevented.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for manufacturing a flash memory device comprising:
forming a plurality of device isolation layers in parallel at predetermined intervals over a semiconductor substrate; and then
forming a gate stack including a tunnel oxide layer, a floating gate, an ONO layer, and a control gate over the semiconductor substrate including the device isolation layers; and then
forming a first dielectric spacer on sidewalls of the gate stack; and then
etching a portion of the first dielectric spacer layer; and then
forming a second dielectric spacer layer over a sidewall of the first dielectric spacer layer after etching the portion of the first dielectric spacer layer.

2. The method of claim 1, wherein etching the portion of the first dielectric spacer comprises removing a portion of the first dielectric spacer corresponding to a spatial position for forming the second dielectric layer.

3. The method of claim 2, wherein etching the portion of the first dielectric spacer comprises performing an etch-back process.

4. The method of claim 1, wherein etching the portion of the first dielectric spacer comprises performing an etch-back process.

5. The method of claim 1, wherein the first dielectric spacer is etched in a direction vertical to the device isolation layer.

6. The method of claim 1, wherein the first dielectric spacer layer comprises an oxide material.

7. The manufacturing method according to claim 1, wherein the second dielectric spacer layer comprises a nitride material.

8. The method of claim 1, wherein the control gate comprises a silicon oxide layer.

9. The method of claim 1, wherein forming the second dielectric spacer layer comprises:
forming a second dielectric layer over the whole surface of the semiconductor substrate including the first dielectric spacer layer; and then
etching the second dielectric spacer layer.

10. The method of claim 9, wherein etching the second dielectric spacer layer comprises performing a dry etching of the second dielectric spacer layer.

11. The method of claim 10, wherein the second dielectric spacer layer is composed of a nitride material.

12. A method comprising:
forming a plurality of device isolation layers over a semiconductor substrate defining active regions; and then
sequentially forming a first oxide layer, a doped polysilicon layer, a second oxide layer, a first nitride layer, a third oxide layer, and a fourth oxide layer over a semiconductor substrate; and then
forming a line pattern including a tunnel oxide pattern, a floating gate pattern, an ONO pattern and a control gate pattern by patterning the first oxide layer, the doped polysilicon layer, the second oxide layer, the first nitride layer, the third oxide layer and the fourth oxide layer; and then
forming a fifth oxide layer over the whole surface of semiconductor substrate including the line pattern; and then
forming a first spacer by etching the fifth oxide layer, the first spacer having a first spacer portion extending vertically on and contacting sidewalls of the line pattern and a second spacer portion extending horizontally over and contacting the uppermost surface of the semiconductor substrate; and then
removing the second spacer portion; and then
forming a second nitride layer over the whole surface of the semiconductor substrate including the first spacer; and then
forming a second spacer on the first spacer portion and over an area of the semiconductor substrate where the second spacer portion was removed.

13. The method of claim 12, wherein forming the first spacer comprises performing an etch-back process on the fifth oxide layer.

14. The method of claim 12, wherein forming the second spacer comprises performing a dry etching process on the second nitride layer.

15. The method of claim 12, wherein the fourth oxide layer comprises silicon oxide.

16. A method comprising:
forming a plurality of device isolation layers over a semiconductor substrate defining active regions; and then
sequentially forming a tunnel oxide layer, a floating gate layer, an ONO layer and a control gate layer over the whole surface of the semiconductor substrate; and then
forming a line pattern including a tunnel oxide pattern, a floating gate pattern, an ONO pattern and a control gate pattern by patterning the tunnel oxide layer, the floating gate layer, the ONO layer and the control gate layer; and then
forming a first dielectric layer over the whole surface of the semiconductor substrate including the line pattern; and then
forming a first dielectric spacer by performing an etch-back process on the first dielectric layer, the first dielectric spacer having a vertically extending portion formed on sidewalls of the line pattern and a horizontally extending portion formed over and contacting the semiconductor substrate; and then
performing an etch process to remove the horizontally extending portion of the first dielectric spacer; and then
forming a second dielectric layer over the whole surface of the semiconductor substrate including the first dielectric spacer; and then
forming a second dielectric spacer layer on the sidewall of the vertically extending portion of the first dielectric spacer and on the area of the semiconductor substrate where the horizontally extending portion of the first dielectric spacer was removed.

17. The method of claim 16, wherein forming the first dielectric spacer comprises:
forming an oxide layer as the first dielectric layer over the whole surface of the semiconductor substrate including the line pattern; and then
performing an etch-back process on the oxide layer.

18. The method of claim 16, wherein forming the second dielectric spacer comprises:
forming a nitride layer as the second dielectric layer over the whole surface of the semiconductor substrate including the first dielectric spacer; and then
performing a dry etching process on the nitride layer.

19. The method of claim 16, wherein the control gate layer comprises silicon oxide.

20. The method of claim 16, wherein the horizontally extending portion of the first dielectric spacer is formed over a region of the semiconductor substrate where the second dielectric spacer is formed.
